(19) United States
(12) Patent Application Publication
(10) Pub. No.: US 2007/0096139 A1
(43) Pub. Date: May 3, 2007

(54) Light emitting diode encapsulation shape control

(75) Inventor: John C. Schultz, Afton, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/265,630

(22) Filed: Nov. 2, 2005

(51) Int. Cl. H01L 33/00

(52) U.S. Cl. 257/100

(57) ABSTRACT

A semiconductor optical device is encapsulated by disposing the semiconductor optical device in a cavity defined by a cavity wall. The cavity wall is coated with a coating material having a first surface energy. An encapsulant having a second surface energy is introduced into the cavity adjacent to the light emitting semiconductor. The encapsulant is solidified to form an outer surface having a shape that is a function of the first surface energy and the second surface energy.

### BACKGROUND

The present invention relates to light emitting diode (LED) devices. In particular, the present invention relates to an encapsulant for an LED having a controlled shape.

LEDs are a desirable choice of light source in part because of their relatively small size, low power/current requirements, rapid response time, long life, robust packaging, variety of available output wavelengths, and compatibility with modern circuit construction. These characteristics help explain the widespread use of LEDs over the past few decades in a multitude of different applications. Improvements to LEDs continue to be made in the areas of efficiency, brightness, and output wavelength, further enlarging the scope of potential applications.

LEDs are typically sold in a packaged form that includes an LED die or chip mounted on a metal header. The header can have a reflective cup in which the LED die is mounted, and electrical leads connected to the LED die. Some packages also include a molded transparent resin that encapsulates the LED die. The encapsulating resin can have a hemispherical or convex front surface (i.e., a convergent lens) to partially collimate light emitted from the die. The resin can also have a flat front surface or concave front surface (i.e., a divergent lens) to transmit a portion of the light through the sidewalls of the package.

An LED die may be encapsulated by filling the reflective cup with encapsulating resin such that the shape of the front opening of the reflective cup controls the shape of the front surface of the encapsulating resin. More specifically, the encapsulating resin forms a convex meniscus along the front opening of the reflective cup such that the larger the opening, the smaller the radius of curvature of the meniscus. However, completely filling the reflective cup with the encapsulating resin can distort the optics of the reflective cup and reduce the collimation of the light emitted from the open end of the reflective cup. This negatively affects the reflective cup's coupling efficiency into a waveguide or optical fiber with a limited numerical aperture.

An LED die may also be encapsulated by completely covering the die with encapsulating resin such that it only fills a portion of the reflective cup. However, because the reflective cup is typically coated with a highly reflective material such as silver or is formed from a polymer optical film, the encapsulating resin may wet the sides of the reflective cup to produce a concave meniscus. A concave meniscus tends to reflect light back toward the sidewalls of the reflective cup and the LED die due to total internal reflection, thereby reducing the potential light output of the LED. In the worst case, the concave meniscus may wick up the sides of the reflective cup enough to significantly impact the properties of the reflective cup, reducing the overall efficiency of the LED. This uncontrolled wicking leads to inconsistent and somewhat uncontrollable contours of the front surface of the encapsulating resin.

### SUMMARY

Methods are disclosed herein for encapsulating a semiconductor optical device. The semiconductor optical device is disposed in a cavity defined by a cavity wall. The cavity wall is coated with a coating material having a first surface energy. An encapsulant having a second surface energy is introduced into the cavity and adjacent to the semiconductor optical device. The encapsulant is solidified to form an optical element having an outer surface with a shape that is a function of the first surface energy and the second surface energy.

Optical devices are disclosed in which a substrate includes a cavity defined by a cavity wall having a coating thereon. A light emitting semiconductor is positioned adjacent to the substrate. An encapsulant fills a portion of the cavity, encapsulates the light emitting semiconductor, and has an optically active surface with a shape that is a function of the relative surface energies of the coating and the encapsulant.

Associated components, systems, and methods are also disclosed.

These and other aspects of the present application will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

FIG. 1 is a perspective cross-sectional view of a light emitting diode (LED) package.

FIG. 2 is a perspective cross-sectional view of an LED package that includes an LED die encapsulated by an encapsulating material having a convex surface.

FIG. 3 is a perspective cross-sectional view of an LED package that includes an LED die encapsulated by a phosphor material and an encapsulating material having a convex surface.

FIG. 4 is a perspective cross-sectional view of an LED package that includes an LED die encapsulated by an encapsulating material having a substantially planar surface.

FIG. 5 is a perspective cross-sectional view of an LED package that includes an LED die encapsulated by an encapsulating material having a substantially planar surface and a phosphor tab thereon.

In the figures, like reference numbers denote like parts.

### DETAILED DESCRIPTION

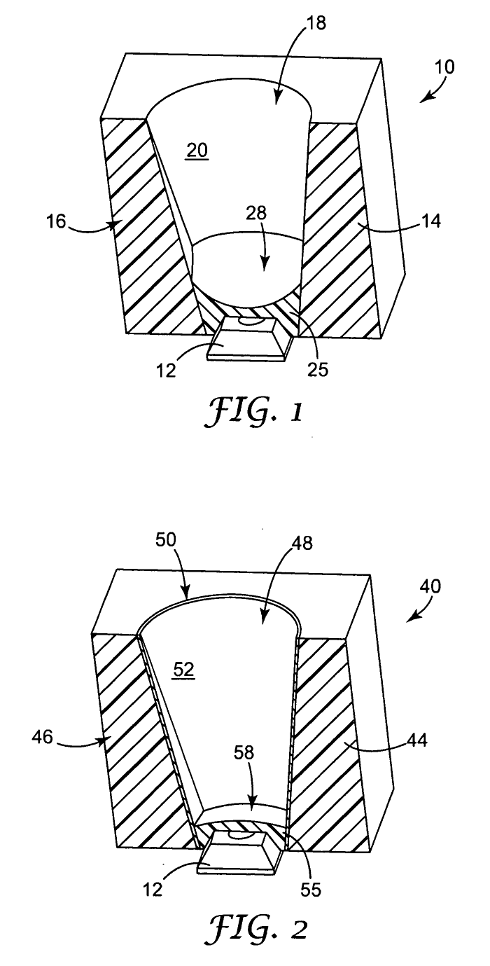

FIG. 1 is a perspective cross-sectional view of a light emitting diode (LED) package 10. LED package 10 includes LED die 12 and substrate 14. Substrate 14 includes carrier or header 16 that includes cavity 18 defined by cavity wall 20. Cavity wall 20 typically comprises a highly reflective material. Cavity wall 20 has sloped sides such that the cross-sectional area of cavity 18 proximate to LED die 12 is less than the cross-sectional area of cavity 18 at the opening of cavity 18. LED die 12 generates light when an electrical current is applied through electrical contacts (not shown). Electrical connections to LED die 12 can be made through substrate 14, by wire bonds or, in the case of a flip chip configuration, by conductive strips connected to contact pads at the bottom of LED die 12.

LED die 12 is encapsulated by encapsulating material 25. Encapsulating material 25 is a low viscosity material that is introduced into cavity 18 in liquid form. Encapsulating material 25 completely covers LED die 12 and fills a portion of cavity 18. The reflective material of cavity wall 20 may comprise such materials as silver or a polymer optical film. These materials have high surface energies relative to encapsulating material 25, which causes the molecules of the liquid encapsulating material 25 to have a stronger attraction to the molecules of cavity wall 20 than to each other. Thus, encapsulating material 25 has a tendency to wet or stick to the highly reflective material of cavity wall 20. Consequently, when encapsulating material 25 is cured, a concave meniscus is formed at front surface 28. The concave meniscus tends to reflect light back toward cavity wall 20 and LED die 12 due to total internal reflection, which reduces the potential light output of LED package 10. In addition, this uncontrolled wicking up cavity wall 20 leads to inconsistent and somewhat uncontrollable contours of front surface 28 of encapsulating material 25.

FIG. 2 is a perspective cross-sectional view of LED package 40 including an encapsulated LED die 12. LED package 40 includes substrate 44 comprising carrier or header 46. Carrier 46 includes cavity 48 defined by cavity wall 50. Cavity wall 50 is sloped or otherwise shaped such that the cross-sectional area of cavity 48 proximate to LED die 12 is less than the cross-sectional area of cavity 48 distal from LED die 12. Cavity wall 50 thus forms a minor opening in which LED die 12 is mounted and a major opening opposite from the minor opening. In some embodiments, cavity 48 can have a square cross-section proximate to LED die 12 and a round cross-section at the opening of cavity 48. In other embodiments, the cross-sectional area of cavity 48 proximate to LED die 12 can be substantially similar to the cross-sectional area of cavity 48 distal from LED die 12.

LED package 40 is fabricated by etching, boring, or otherwise forming cavity 48 in carrier 46, and then coating or treating the resulting cavity wall 50 with coating material 52. Coating material 52 is in some cases a low surface energy material that limits wetting of materials on cavity wall 50. Coating material 52 can also be selected to have a moderate or high surface energy depending on the desired shape of the encapsulant meniscus. In some embodiments, coating material 52 can be a monolayer coating of material (i.e., one molecule thick). Next, carrier 46 is positioned adjacent to LED die 12 such that LED die 12 is positioned in the minor opening of cavity 48 and opposite from the major opening of cavity 48. A curable encapsulating material 55 is then dispensed into cavity 48 in liquid form (such as by a dispensing nozzle) to form a liquid mass that completely covers LED die 12 and fills a portion of cavity 48. In one embodiment, encapsulating material is a light transmissive material having a refractive index of at least approximately 1.5. The liquid encapsulating material 55 has a shape determined to some extent by the density, viscosity, volume, and surface tension of the curable material, as well as environmental conditions such as local gravity and temperature.

In addition, the shape of liquid encapsulating material 55 is determined by the size of cavity 48 and the relative surface energies of coating material 52 and liquid encapsulating material 55. Thus, coating material 52 can be selected to have a surface energy relative to encapsulating material 55 to produce a meniscus at the front surface of the encapsulating material 55 having the desired shape. In the embodiment shown in FIG. 2, coating material 52 has a low surface energy relative to liquid encapsulating material 55. Consequently, the molecules of liquid encapsulating material 55 are more strongly attracted to each other than to cavity wall 50 (i.e., the cohesive forces are stronger than the adhesive forces). The size of cavity 48 and the relative surface energies of coating material 52 and encapsulating material 55 cause the liquid encapsulating material 55 to form a convex meniscus at front surface 58.

LED package 40 is then exposed to radiation of sufficient energy and suitable wavelength to cause full curing of the liquid encapsulating material 55. Useful wavelengths and intensities of radiation used for curing encapsulating material 55 include any that induce curing chemistry and are absorbed by some portion of encapsulating material 55. In some embodiments, useful radiation includes ultraviolet (UV) light with a wavelength of less than 400 nm.

As a result of the curing process, encapsulating material 55 is solidified and produces a front surface 58 having a smooth, convex shape (i.e., a convergent lens shape). In alternative embodiments, coating material 52 can be selected to have a surface energy such that encapsulating material 55 forms a substantially planar shape or a concave shape (i.e., a divergent lens shape). By coating cavity wall 50 with an appropriate coating material 52, the shape of front surface 58 is highly controllable without the need to etch, mold, machine, or otherwise modify the shape of the solidified encapsulating material 55. The finish of front surface 58 is also of high quality since it is formed without touching any other surfaces. Thus, an LED package 40 having preferred optical properties may be produced by treating the cavity wall 50 with coating material 52 having a surface energy based on the surface energy of encapsulating material 55, resulting in a higher proportion of the light exiting from the LED package 40 at desirable angles. In some embodiments, carrier 46 is made of a dissolvable material, and is removed after the curing process by a dissolving step such that the encapsulated LED die 12 may be isolated.

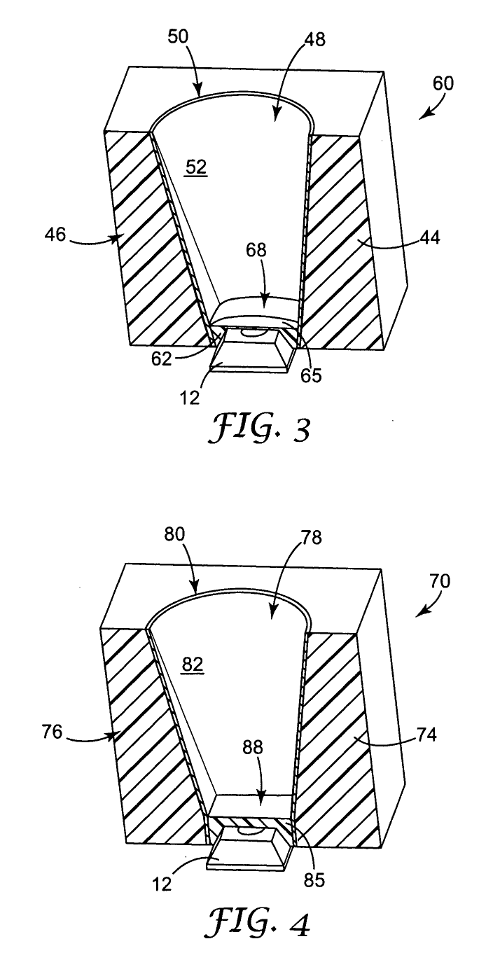

FIG. 3 is a perspective cross-sectional view of another LED package 60. Carrier 46 of LED package 60 is prepared similarly to carrier 46 of LED package 40 (FIG. 2). In particular, cavity wall 50 is first coated with coating material 52, which is a low surface energy material that limits wetting of materials on cavity wall 50. In one embodiment, coating material 52 is a monolayer coating of material (i.e., one molecule thick). Next, carrier 46 is positioned adjacent to LED die 12 such that LED die 12 is positioned in cavity 48 opposite from the opening of cavity 48.

Phosphor material 62 is then introduced into cavity 48 and adjacent to LED die 12. Phosphor material 62 may be incorporated into LED package 60 to generate white light from a blue LED die, for example. One example of a suitable phosphor material 62 is a Y₃Al₅O₁₂:Ce³⁺ (YAG:Ce) phosphor. Another example of a suitable phosphor material 62 is SrGa₂S₄:Eu (HPL63/F-F1) from Phosphor Technology Ltd., Herts, England. A curable encapsulating material 65 is then dispensed into cavity 48 in liquid form (such as by a dispensing nozzle) to form a liquid mass that completely covers phosphor material 62 and fills a portion of cavity 48. In one embodiment, encapsulating material is a light transmissive material having a refractive index of at least approximately 1.5. As described above, the liquid encapsulating material 65 has a shape determined to some extent by chemical and environmental conditions, as well as the size of cavity 48 and the relative surface energies of coating material 52 and liquid encapsulating material 65. Consequently, in the embodiment shown in FIG. 3, the relative surface energies of coating material 52 and encapsulating material 65 cause the liquid encapsulating material 65 to form a convex meniscus at front surface 68. LED package 60 is then exposed to radiation of sufficient energy and suitable wavelength to cause full curing of the liquid encapsulating material 65. As a result of the curing process, encapsulating material 65 is solidified such that front surface 68 maintains a smooth, convex shape (i.e., a convergent lens shape)

A heavily doped phosphor, such as phosphor material 62, is a highly thixotropic material that becomes less viscous when agitated and thus does not provide the desired convex front surface for emitting light from LED package 60. However, by depositing encapsulating material 65 on top of the phosphor material 62, the desired convex front surface is formed due to the relative surface energies of coating material 52 and encapsulating material 65. The addition of the phosphor is advantageous in that some or all of the light output from LED die 12 is converted to longer light wavelengths based on the phosphor used, typically to produce an overall white light output.

FIG. 4 is a perspective cross-sectional view of another LED package 70, which includes substrate 74 comprising carrier or header 76. Carrier 76 includes cavity 78 defined by cavity wall 80. Cavity wall 80 has substantially planar sides proximate to the minor opening of cavity 78 and curved sides that extend to the major opening of cavity 78. Cavity wall 80 forms a minor opening in which LED die 12 is mounted and a major opening opposite from the minor opening. In one embodiment, cavity 78 has a square cross-section proximate to the minor opening.

Similar to other embodiments, LED package 70 can be fabricated by etching, boring, or otherwise forming cavity 78 in carrier 76, and then coating or treating the resulting cavity wall 80 with coating material 82. Coating material 82 can be a low surface energy material that limits wetting of materials on cavity wall 80. Coating material 82 can alternatively be selected to have a moderate or high surface energy depending on the desired shape of the encapsulant meniscus. In some embodiments, coating material 72 is a monolayer coating of material (i.e., one molecule thick). Next, carrier 76 is positioned adjacent to LED die 12 such that LED die 12 is positioned proximate to the minor opening of cavity 78 opposite the major opening of cavity 78. A curable encapsulating material 85 is then dispensed into cavity 78 in liquid form (such as by a dispensing nozzle) to form a liquid mass that completely covers LED die 12 and fills a portion of cavity 78. In one embodiment, encapsulating material is a light transmissive material having a refractive index of at least approximately 1.5. The liquid encapsulating material 85 has a shape determined to some extent by chemical and environmental conditions, as well as by the size of cavity 78 and the relative surface energies of coating material 82 and liquid encapsulating material 85. In the embodiment shown in FIG. 4, the relative surface energies of coating material 82 and encapsulating material 85 cause the liquid encapsulating material 85 to form a substantially planar meniscus at front surface 88.

LED package 70 is then exposed to radiation of sufficient energy and suitable wavelength to cause full curing of the liquid encapsulating material 85. As a result of the curing process, encapsulating material 85 is solidified such that front surface 88 maintains a smooth, substantially planar shape. A substantially planar shape can minimize the increase in area of the effective emitting surface (i.e., front surface 88) of encapsulating material 85, thereby minimizing the increase in étendue of the source. In addition, the distance between the minor and major openings of cavity 78 may be minimized so that the effective LED emission area is the major opening of cavity 78. The planar front surface 88 provides a reduction in light emitted through front surface 88 and provides an associated increase in light emitted through the sides of encapsulating material 85.

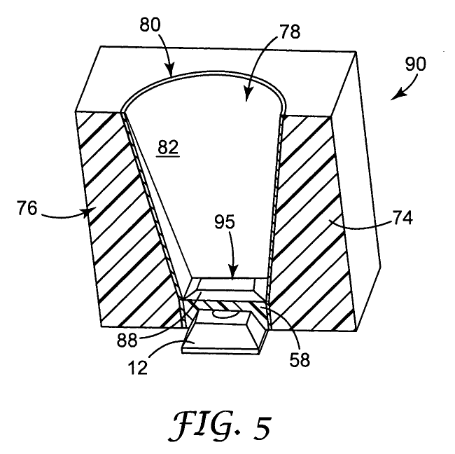

FIG. 5 is a perspective cross-sectional view of another LED package 90. LED package 90 is substantially similar to LED package 70 of FIG. 4, but includes the addition of phosphor tab 92 affixed to front surface 88 of encapsulating material 85. An advantage of this embodiment is that front surface 95 of phosphor tab 92 may be shaped as desired while having little or no losses due to Fresnel reflections or total internal reflection at the interface between encapsulating material 85 and phosphor tab 92 (provided the refractive indices of encapsulating material 85 and phosphor tab 92 are substantially matched). In addition, a wavelength-selective multilayer film can optionally be introduced between encapsulating material 85 and phosphor tab 92 to improve the overall efficiency of LED package 90.

### EXAMPLE AND COMPARATIVE EXAMPLE

A Revision 8 Cree reflector was used as a carrier. This carrier had a cavity extending through it with a minor opening shaped as a 350 μm square and a major opening shaped as a circle with a diameter of 650 μm. The length of the cavity, measured from the minor opening to the major opening, was about 0.9 mm. The cavity wall was coated with a low surface energy coating of a mixture of mono- and di[2-(perfluorooctyl)ethyl]phosphate dissolved in methyl tertbutyl ether at a concentration of 0.25% weight to weight (w/w). The entire package was dried overnight at room temperature. The coated cavity was then partially filled with Dow Corning Sylgard® 182 silicone adhesive, which was used as an encapsulant. A 0.002 inch thick wet hand spread of this adhesive was formed, and the carrier was then pressed into this adhesive layer allowing the adhesive to fill the cavity through its minor opening until the cavity was about ¾ full. The reflector with adhesive was then cured at 150° C. for 30 minutes.

In order to examine the shape of the meniscus formed by the adhesive layer, the reflector was cut in half, and the cured encapsulant was removed. Examination revealed that the above preparation produced a convex meniscus shape at the outer surface of the encapsulant.

For purposes of comparison, the process was repeated, except that the cavity wall was left uncoated. This comparison preparation produced a deeply concave meniscus shape at the outer surface of the encapsulant. The concave shape was formed by the wicking action of the liquid encapsulant up the sidewall of the uncoated cavity.

In summary, semiconductor optical devices can be encapsulated by disposing the semiconductor optical device in a cavity defined by a cavity wall. The cavity wall can be coated with a coating material having a first surface energy. An encapsulant having a second surface energy can be introduced into the cavity adjacent to the semiconductor optical device. The encapsulant is solidified to form an outer surface with a shape that is a function of the first surface energy and the second surface energy. The coating material, the encapsulant, or both are selected based on their surface energies to produce a desired outer surface shape, thus producing an optical element having desired optical properties.

Although the present invention has been described with reference to preferred embodiments, workers skilled in the art will recognize that changes may be made in form and detail without departing from the spirit and scope of the invention.

1. A method of encapsulating a semiconductor optical device, the method comprising:
disposing the semiconductor optical device in a cavity defined by a cavity wall that is coated with a coating material having a first surface energy;
introducing an encapsulant having a second surface energy into the cavity adjacent to the semiconductor optical device; and
solidifying the encapsulant to form an outer surface having a shape that is a function of the first surface energy and the second surface energy.

2. The method of claim 1, wherein the first surface energy is less than the second surface energy.

3. The method of claim 1, wherein the first surface energy is greater than the second surface energy.

4. The method of claim 1, wherein the first surface energy is substantially equal to the second surface energy.

5. The method of claim 1, and further comprising:
providing a phosphor material adjacent to the semiconductor device.

6. The method of claim 1, wherein the semiconductor device comprises a light emitting diode (LED) die.

7. The method of claim 1, wherein the coating material is a monolayer of coating material.

8. The method of claim 1, wherein the optically active surface has a convex shape.

9. The method of claim 1, wherein the optically active surface is substantially planar.

10. The method of claim 1, wherein the optically active surface has a concave shape.

11. The method of claim 1, wherein the disposing step comprises:
providing a substrate including a cavity defined by a cavity wall; and
positioning the semiconductor optical device adjacent to the cavity.

12. The method of claim 11, wherein the substrate comprises a dissolvable material.

13. The method of claim 11, further comprising:
dissolving the substrate after the solidifying step.

14. The method of claim 1, wherein the cavity wall is coated by coating at least a portion of the cavity wall with the coating material having the first surface energy.

15. An optical device, comprising:
a substrate including a cavity defined by a cavity wall having a coating thereon;
a light emitting semiconductor positioned adjacent to the substrate; and
an encapsulant that fills a portion of the cavity, encapsulates the light emitting semiconductor, and has an optically active surface with a shape that is a function of the relative surface energies of the coating and the encapsulant.

16. The optical device of claim 15, wherein the coating is a monolayer of coating material.

17. The optical device of claim 15, and further comprising:
a phosphor material positioned proximate to the light emitting semiconductor.
